(19) United States
(12) Patent Application Publication
(10) Pub. No.: US 2025/0004056 A1
(43) Pub. Date: Jan. 2, 2025

(54) DATA ACQUISITION CIRCUIT AND METHOD FOR BATTERY MODULE

(71) Applicant: Sungrow Energy Storage Technology Co., Ltd., Hefei (CN)

(72) Inventors: Lin Wang, Hefei (CN); Haowu Liu, Hefei (CN); Fei Chen, Hefei (CN); Wenming Zheng, Hefei (CN); Yao Zhao, Hefei (CN); Shuxian Wang, Hefei (CN); Jian Yu, Hefei (CN)

(73) Assignee: Sungrow Energy Storage Technology Co., Ltd., Hefei (CN)

(21) Appl. No.: 18/414,441

(22) Filed: Jan. 16, 2024

(30) Foreign Application Priority Data
Jun. 30, 2023 (CN) 202310808994.9

(51) Int. Cl. G01R 31/3835; H01M 10/48

(52) U.S. Cl. CPC G01R 31/3835; H01M 10/482; H01M 10/486

(57) ABSTRACT

A data acquisition circuit and method for a battery module are provided. The circuit includes a signal processing board and a signal acquisition board. The signal processing board includes an acquisition circuit module. The signal acquisition board is provided with n voltage acquisition chips each provided with a temperature sensor, and n−1 cells of the battery module. The signal acquisition board is connected to the signal processing board through a connector. The first end of the (m−1)^{th} voltage acquisition chip is connected to the negative electrode of the (m−1)^{th} cell. The first end of the m^{th} voltage acquisition chip is connected to the positive electrode of the (m−1)^{th} cell. The second end of the voltage acquisition chip is connected to the signal processing board through the connector. The first end of the temperature sensor is connected to the acquisition circuit module in the signal processing board.

The present application claims priority to Chinese Patent Application No. 202310808994.9, titled “DATA ACQUISITION CIRCUIT AND METHOD FOR BATTERY MODULE”, filed on Jun. 30, 2023 with the China National Intellectual Property Administration, which is incorporated herein by reference in its entirety.

### FIELD

The present application relates to the technical field of energy storage, and specifically to a data acquisition circuit and a data acquisition method applied to a battery module.

### BACKGROUND

Nowadays “carbon neutrality” and “carbon peak” are drawing increasing attention recently, which in turn promotes rapid development of energy storage. Centralized energy storage is an important branch of the energy storage in power system. Due to high energy density, it is of vital importance to use batteries for centralized energy storage in safety.

At present, key cells in each battery module for centralized energy storage are sampled to sense temperature and voltage, to detect a malfunction of the battery module. However, failure to take account of all cells in the battery module results in inaccurate determination about whether the battery module is functioning properly or not. Consequently, whether the battery module in operation is completely safe remains unknown.

### SUMMARY

In view of this, a data acquisition circuit and a data acquisition method applied to a battery module are provided according to the present application, so that whether the battery module is functioning improperly can be accurately determined, thereby improving the safety.

The technical solutions are described below.

A data acquisition circuit applied to a battery module is according to a first aspect of the present application. The data acquisition circuit includes a signal processing board and a signal acquisition board. The signal processing board includes an acquisition circuit module. The signal acquisition board is provided with n voltage acquisition chips and n−1 cells of the battery module. The voltage acquisition chips each are provided with a temperature sensor. The signal acquisition board is connected to the signal processing board through a connector. A first end of an (m−1) th voltage acquisition chip among the n voltage acquisition chips is connected to a negative electrode of an (m−1) th cell among the n−1 cells, and a first end of an m^{th} voltage acquisition chip among the n voltage acquisition chips is connected to a positive electrode of the (m−1) th cell. For each of the n voltage acquisition chips, a second end of the voltage acquisition chip is connected to the signal processing board through the connector, and the voltage acquisition chip is configured to acquire a voltage parameter of the cell connected to the voltage acquisition chip and transmit the acquired voltage parameter to the signal processing board. m is greater than or equal to 2 and less than or equal to n. A first end of the temperature sensor is connected to the acquisition circuit module, and the temperature sensor is configured to acquire a temperature parameter of the cell connected to the voltage acquisition chip corresponding to the temperature sensor and transmit the acquired temperature parameter to the signal processing board.

Optionally, the signal acquisition board is n in number and the connector is n in number. An m^{th} signal acquisition board among the n signal acquisition boards is connected to the signal processing board through an m^{th} connector among the n connectors. An (m−1) th connector among the n connectors is arranged under the m^{th} signal acquisition board. An (m−1) th signal acquisition board among the n signal acquisition boards is connected to the signal processing board through the (m−1) th connector.

Optionally, the acquisition circuit module is n in number. First ends of temperature sensors on a first signal acquisition board among the n signal acquisition boards are connected to a first acquisition circuit module among the n acquisition circuit modules on the signal processing board. First ends of the temperature sensors on the m^{th} signal acquisition board are connected to an m^{th} acquisition circuit module among the n acquisition circuit modules on the signal processing board.

Optionally, the acquisition circuit module includes n temperature signal processing circuits. A first end of a first temperature sensor in the signal acquisition board is connected to a first temperature signal processing circuit among the n temperature signal processing circuits in the acquisition circuit module. A first end of an m^{th} temperature sensor in the signal acquisition board is connected to an m^{th} temperature signal processing circuit among the n temperature signal processing circuits in the acquisition circuit module.

Optionally, the acquisition circuit module further includes n filtering protection circuits. the first end of the first temperature sensor in the signal acquisition board is connected to a first end of a first filtering protection circuit among the n filtering protection circuits in the acquisition circuit module, a second end of the first filtering protection circuit is connected to the first temperature signal processing circuit, and a third end of the first filtering protection circuit is grounded. the first end of the m^{th} temperature sensor in the signal acquisition board is connected to a first end of an m^{th} filtering protection circuit among the n filtering protection circuits in the acquisition circuit module, a second end of the m^{th} filtering protection circuit is connected to the m^{th} temperature signal processing circuit, and a third end of the m^{th} filtering protection circuit is grounded.

Optionally, the signal acquisition board comprises n fuses. second ends of the n voltage acquisition chips are connected to first ends of the n fuses, respectively. second ends of the n fuses are connected to the connector, wherein the n voltage acquisition chips are connected to the signal acquisition board through the respective fuses and the connector.

Optionally, the signal acquisition board further includes a first target fuse. A third end of a first voltage acquisition chip among the n first voltage acquisition chips is connected to a first end of the first target fuse, and a second end of the first target fuse is connected to a ground terminal of the signal acquisition module through the connector.

Optionally, the signal acquisition board further includes a second target fuse. A second end of the temperature sensor is connected to a first end of the second target fuse, and a second end of the second target fuse is connected to a ground terminal of the signal acquisition module through the connector.

Optionally, the signal acquisition board further includes n current limiting resistors. A third end of a first temperature sensor among the n temperature sensors is connected to a first end of a first current limiting resistor among the n current limiting resistors, and a second end of the first current limiting resistor is connected to the first end of the second target fuse. a third end of an m^{th} temperature sensor among the n current limiting resistors is connected to a first end of an m^{th} current limiting resistor among the n current limiting resistors, and a second end of the m^{th} current limiting resistor is connected to the first end of the second target fuse. the second end of the second target fuse is connected to the ground terminal of the signal acquisition module through the connector.

Optionally, the signal acquisition board further comprises a third target fuse. a third end of an nth voltage acquisition chip among the n voltage acquisition chips is connected to the first end of the first target fuse. the second end of the first target fuse is connected to the signal processing board through the connector.

A data acquisition method for a battery module is provided in a second aspect of the present application. The method is applicable to the data acquisition circuit in the first aspect of the application. The data acquisition circuit includes a signal processing board and a signal acquisition board. The signal processing board includes an acquisition circuit module. the signal acquisition board is provided with n voltage acquisition chips and n−1 cells of the battery module. The n voltage acquisition chips each are provided with a temperature sensor. The method includes: acquiring voltage parameters of cells connected to voltage acquisition chips and transmitting the acquired voltage parameters to the signal processing board, by the voltage acquisition chips, respectively; and acquiring temperature parameters of the cells connected to the voltage acquisition chips where temperature sensors are arranged and transmitting the acquired temperature parameters to the signal processing board by the temperature sensors, respectively, for the signal processing board to analyze the received voltage parameters and the received temperature parameters to determine whether the battery module is operating properly.

The data acquisition circuit according to the application includes a signal processing board and a signal acquisition board. The signal processing board includes an acquisition circuit module. The signal acquisition board is provided with n voltage acquisition chips and n−1 cells of the battery module. The n voltage acquisition chips each are provided with a temperature sensor. The signal acquisition board is connected to the signal processing board through a connector. The first end of the (m−1)^{th} voltage acquisition chip is connected to the negative electrode of the (m−1)^{th} cell. The first end of the m^{th} voltage acquisition chip is connected to the positive electrode of the (m−1)^{th} cell. The second end of the voltage acquisition chip is connected to the signal processing board through the connector. The voltage acquisition chip acquires the voltage parameter of the cell connected to the voltage acquisition chip and transmit the acquired voltage parameter to the signal processing board. m is greater than or equal to 2 and less than or equal to n. The first end of the temperature sensor is connected to the acquisition circuit module in the signal processing board. The temperature sensor acquires the temperature parameter of the cell connected to the corresponding voltage acquisition chip, and transmits the acquired temperature parameter to the signal processing board. The signal processing board analyzes the received voltage parameters and temperature parameters to determine whether the battery module is operating properly. In this way, all cells in the battery module can be taken into account in the determination of whether the battery module is functioning properly or not, and the safety of the battery module cannot be guaranteed.

### BRIEF DESCRIPTION OF DRAWINGS

The drawings in the embodiments or the conventional technology are described briefly below to illustrate the technical solutions in the embodiments of the present disclosure or the conventional technology more clearly. The drawings in the following description illustrate only embodiments of the present disclosure, those skilled in the art may obtain other drawings according to the provided drawings without any creative effort.

FIG. 1 is a schematic structural diagram illustrating a data acquisition circuit applied to a battery module according to an embodiment of the present application;

FIG. 2 is a schematic structural diagram illustrating the data acquisition circuit according to another embodiment of the present application;

FIG. 3 is a structural diagram illustrating a flexible printed circuit (FPC) as a signal acquisition board according to an embodiment of the present application; and

FIG. 4 is a schematic flowchart illustrating a data acquisition method applied to a battery module according to an embodiment of the present application.

### DETAILED DESCRIPTION OF EMBODIMENTS

The following will clearly and completely describe the technical solutions in the embodiments of the present application with reference to the drawings in the embodiments of the present disclosure. The described embodiments are some rather than all the embodiments of the present disclosure. Based on the embodiments disclosed herein, all other embodiments obtained by those skilled in the art without creative efforts fall within the protection scope of the present disclosure.

In this application, the term “include”, “comprise” or any other variation thereof is intended to be non-exclusive such that a process, method, article, or device including a set of elements includes not only those elements listed but also other elements not specifically listed, or elements inherent in such process, method, article, or device. Without further limitations, an element defined by the phrase “comprising a . . . ” does not preclude the presence of additional identical elements in the process, method, article, or device that includes the element.

It should be noted that terms such as “first” and “second” herein are only for distinguishing devices, modules or units, instead of limiting sequence or interdependence of functions performed by these devices, modules or units.

It should be noted that the determiners of “one” and “multiple” herein are illustrative rather than restrictive. Those skilled in the art should understand that such determiners should be understood as “one or more” unless the context clearly indicates otherwise.

A data acquisition circuit applied to a battery module is provided according to the present application. The data acquisition circuit can acquire temperature parameters and voltage parameters of all cells in the battery module.

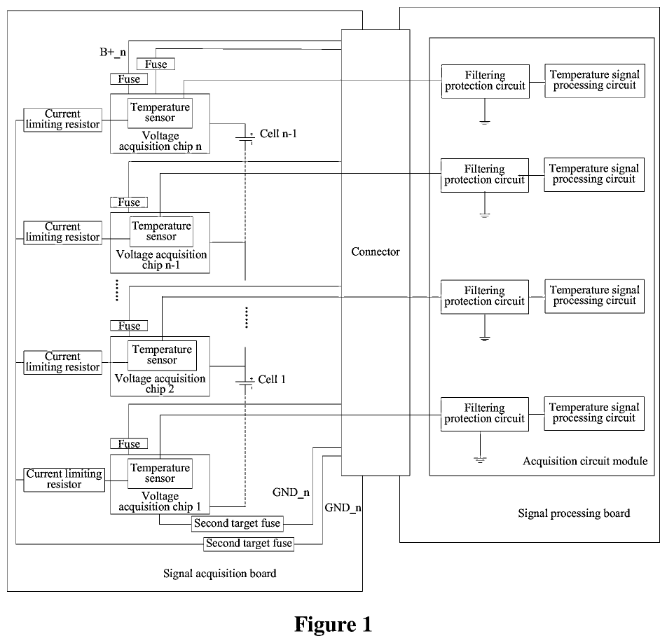

FIG. 1 is a schematic structural diagram illustrating the data acquisition circuit according to an embodiment of the present application. The data acquisition circuit includes a signal processing board and a signal acquisition board. The signal processing board is provided with an acquisition circuit module. The signal acquisition board is provided with n voltage acquisition chips and n−1 cells. Each of the voltage acquisition chips is provided with a temperature sensor.

The signal acquisition board is connected to the signal processing board through a connector.

It should be noted that how the signal acquisition board is connected to the signal processing board through the connector is not limited herein but depends on actual applications. Further, details about the connector are not limited herein but depend on actual applications.

In some embodiments, the voltage acquisition chip arranged on the signal acquisition board is a nickel chip. Alternatively, the voltage acquisition chip may be made of other materials.

A first end of an (m−1)^{th} voltage acquisition chip is connected to a negative electrode of an (m−1)^{th} cell. A first end of an m^{th} voltage acquisition chip is connected to a positive electrode of the (m−1)^{th} cell.

A second end of the voltage acquisition chip is connected to the signal processing board through the connector. The voltage acquisition chip is configured to acquire a voltage parameter of the cell connected to the voltage acquisition chip and transmit the acquired voltage parameter to the signal processing board. m is greater than or equal to 2 and less than or equal to n.

In the embodiments of the present application, the (m−1)^{th} voltage acquisition chip, the m^{th} voltage acquisition chip and the (m−1)^{th} cell form a voltage acquisition loop for the (m−1)^{th} cell. The (m−1)^{th} voltage acquisition chip acquires electric potential at the negative electrode of the (m−1) th cell. The m^{th} voltage acquisition chip acquires electric potential at the positive electrode of the (m−1)^{th} cell.

In practice, the signal processing board receives the electric potential at the negative electrode of the (m−1)^{th} cell transmitted by the (m−1)^{th} voltage acquisition chip and the electric potential at the positive electrode of the (m−1)^{th} cell transmitted by the m^{th} voltage acquisition chip, and determines the voltage across the (m−1)^{th} cell based on the electric potential at the negative electrode of the (m−1)^{th} cell and the electric potential at the positive electrode of the (m−1)^{th} cell.

A first end of the temperature sensor is connected to the acquisition circuit module in the signal processing board. The temperature sensor is configured to acquire a temperature parameter of the cell connected to the corresponding voltage acquisition chip, and transmit the acquired temperature parameter to the signal processing board.

In the embodiments of the present application, the temperature sensor is placed on the voltage acquisition chip to conduct heat generated by the cell rapidly by fully exploiting thermal conductivity of the voltage acquisition chip. Therefore, the temperature of the cell can be measured timely and accurately. In addition, arranging the temperature sensor on the voltage acquisition chip can reduce the data acquisition circuit in size.

In practice, the signal acquisition board is a flexible printed circuit (FPC) or the like, depending on actual applications.

In practice, the temperature sensor is an NTC (Negative Temperature Coefficient) thermistor or the like, depending on actual applications.

In some embodiments, the signal acquisition board in the data acquisition circuit according to the present application further includes n fuses.

The second end of the voltage acquisition chip is connected to a first end of the corresponding fuse. A second end of the fuse is connected to the connector. Therefore, the voltage acquisition chip is connected to the signal acquisition board through the fuse and the connector.

In practice, the fuse connected to the corresponding voltage acquisition chip can melt timely in case of failure, for example, a short circuit, when the voltage acquisition chip is sensing voltage, to prevent the data acquisition circuit from burning.

In some embodiments, the signal acquisition board in the data acquisition circuit according to the present application also includes a first target fuse and a second target fuse.

A third end of the first voltage acquisition chip is connected to a first end of the first target fuse. A second end of the first target fuse is connected to a ground terminal of the acquisition circuit module on the signal processing board through the connector.

A second end of the temperature sensor is connected to a first end of the second target fuse. A second end of the second target fuse is connected to the ground terminal of the acquisition circuit module of the signal processing board through the connector.

Two general ground wires of the signal acquisition board are connected to the signal processing board, and therefore a corresponding loop is formed, greatly simplifying a layout of wiring between the signal acquisition board and the signal processing board. In view of this, the data acquisition circuit can be maximally reduced in size, facilitating mass production and reduction in costs.

The fuse connected to the general ground wire of the signal acquisition board can melt timely in case of failure, for example, a short circuit, between the temperature sensor or the voltage acquisition chip and the general ground wire, to prevent the data acquisition circuit from burning.

Furthermore, the signal acquisition board in the data acquisition circuit according to the present application also includes a third target fuse.

A third end of the n^{th} voltage acquisition chip is connected to a first end of the second target fuse. A second end of the third target fuse is connected to the signal processing board through the connector.

In some embodiments, the acquisition circuit module of the signal processing board in the data acquisition circuit according to the present application includes n temperature signal processing circuits.

A first end of the first temperature sensor in the signal acquisition board is connected to the first temperature signal processing circuit in the acquisition circuit module.

A first end of the m^{th} temperature sensor in the signal acquisition board is connected to the m^{th} temperature signal processing circuit in the acquisition circuit module.

In some embodiments of the present application, a filtering protection circuit is added upstream of the corresponding temperature signal processing circuit of the signal acquisition board, in order to prevent an excessive potential difference between temperature sampling circuits after the target fuse on the general ground wire connected to the signal acquisition board melts. Otherwise, the excessive potential difference may affect other components on the signal processing board.

In some embodiments, the acquisition circuit module of the signal processing board in the data acquisition circuit according to the present application includes n filtering protection circuits.

The first end of the first temperature sensor in the signal acquisition board is connected to a first end of the first filtering protection circuit in the acquisition circuit module. A second end of the first filtering protection circuit is connected to the first temperature signal processing circuit. A third end of the filtering protection circuit is grounded.

The first end of the m^{th} temperature sensor in the signal acquisition board is connected to a first end of the m^{th} filtering protection circuit in the acquisition circuit module. A second end of the m^{th} filtering protection circuit is connected to the m^{th} temperature signal processing circuit. A third terminal of the m^{th} filtering protection circuit is grounded.

In addition, adding the filtering protection circuit upstream of the temperature signal processing circuit of the signal acquisition board can effectively filter out interference.

In some embodiments, the signal acquisition board in the data acquisition circuit according to the present application also includes n current limiting resistors.

A third end of the first temperature sensor in the signal acquisition board is connected to a first end of the first current limiting resistor. A second end of the first current limiting resistor is connected to the first end of the second target fuse.

A third end of the m^{th} temperature sensor in the signal acquisition board is connected to a first end of the m^{th} current limiting resistor. A second end of the m^{th} current limiting resistor is connected to the first end of the second target fuse.

The second end of the second target fuse is connected to the ground terminal of the signal acquisition module of the signal processing board through the connector.

In practice, the general ground wire of the signal acquisition board and the voltage acquisition chip are electrically equipotential when the voltage acquisition chip or the signal acquisition board is short-circuited. Therefore, the general ground wire of the signal acquisition board is connected to the general ground terminal of the signal processing board through the current limiting resistor and the temperature sensor, to effectively avoid damages resulted from excessive current.

The current limiting resistor can effectively prevent overcurrent when the voltage acquisition chip or the temperature sensor is short-circuited. Further, when a loop formed by the temperature sensor, the voltage acquisition chip and the cell is short-circuited, the current limiting resistor can effectively prevent overcurrent and convert capacitive current through the circuit into resistive current, thereby effectively preventing electrical arc in the signal acquisition board.

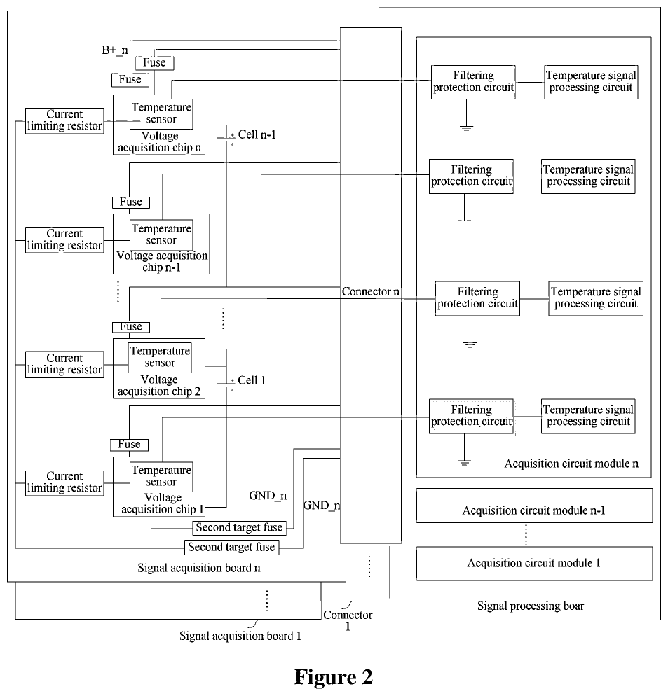

In some embodiments, referring to FIG. 2 in conjunction with FIG. 1, the data acquisition circuit according to the present application includes n signal acquisition boards and n connectors. The signal processing board includes n acquisition circuit modules.

First ends of all temperature sensors on the first signal acquisition board are connected to the first acquisition circuit module on the signal processing board.

First ends of all temperature sensors on the m^{th} signal acquisition board are connected to the m^{th} acquisition circuit module on the signal processing board.

FIG. 2 illustrates connectors for connecting only two adjacent signal acquisition boards that are stacked, for better understanding of the data acquisition circuit. FIG. 2 does not limit the size of the connector.

For example, the size of the connector is determined for the purpose of mistake-proofing.

First ends of all temperature sensors on the first signal acquisition board are connected to the first acquisition circuit module on the signal processing board.

First ends of all temperature sensors on the m^{th} signal acquisition board are connected to the m^{th} acquisition circuit module on the signal processing board.

In practice, the signal acquisition boards are stacked due to the increasing energy density inside the battery module. The (m−1)^{th} connector is arranged on the m^{th} signal acquisition board. The m^{th} signal acquisition board is connected to the signal processing board through the m^{th} connector. Therefore, the signal acquisition board is prevented from bending and thus no stress results, and space for arranging the signal acquisition boards can be saved.

The data acquisition circuit includes n signal acquisition boards and n connectors in case of a large number of cells in the battery module, to comprehensively monitor and protect the battery module, for the battery module to operate stably and reliably.

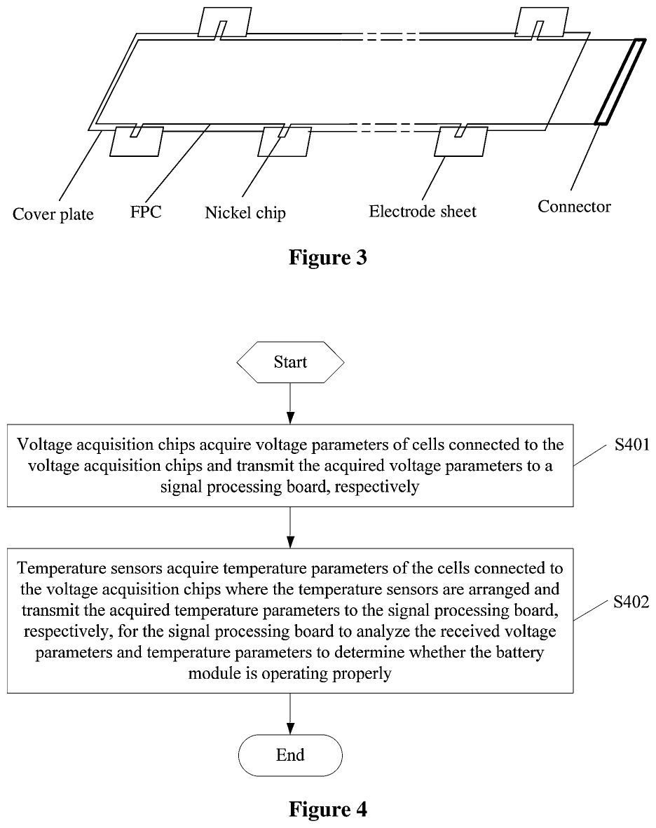

For example, the signal acquisition board in the FPC. A cover is arranged under the FPC, and electrode sheets and nickel sheets are arranged at the edge of the FPC, as shown in FIG. 3.

The data acquisition circuit according to the application includes a signal processing board and a signal acquisition board. The signal processing board includes an acquisition circuit module. The signal acquisition board is provided with n voltage acquisition chips and n−1 cells. The n voltage acquisition chips each are provided with a temperature sensor. The signal acquisition board is connected to the signal processing board through a connector. The first end of the (m−1)^{th} voltage acquisition chip is connected to the negative electrode of the (m−1)^{th} cell. The first end of the m^{th} voltage acquisition chip is connected to the positive electrode of the (m−1)^{th} cell. The second end of the voltage acquisition chip is connected to the signal processing board through the connector. The voltage acquisition chip acquires the voltage parameter of the cell connected to the voltage acquisition chip and transmit the acquired voltage parameter to the signal processing board. m is greater than or equal to 2 and less than or equal to n. The first end of the temperature sensor is connected to the acquisition circuit module in the signal processing board. The temperature sensor acquires the temperature parameter of the cell connected to the corresponding voltage acquisition chip, and transmits the acquired temperature parameter to the signal processing board. The signal processing board analyzes the received voltage parameters and temperature parameters to determine whether the battery module is operating properly. In this way, all cells in the battery module can be taken into account in the determination of whether the battery module is functioning properly or not, and the safety of the battery module cannot be guaranteed.

FIG. 4 shows a data acquisition method for a battery module according to the embodiments of the present application. The data acquisition method is applicable to the data acquisition circuit according to the above embodiments of the present application. The data acquisition method includes the following steps S401 to S402.

In S401, voltage acquisition chips acquire voltage parameters of cells connected to the voltage acquisition chips and transmit the acquired voltage parameters to a signal processing board, respectively.

In the embodiments, the cell and two voltage acquisition chips connected to the cell form a voltage acquisition loop, to acquire the voltage parameter of the cell.

For example, the (m−1)^{th} voltage acquisition chip, the m^{th} voltage acquisition chip and the (m−1)^{th} cell form a voltage acquisition loop for the (m−1)^{th} cell. The (m−1)^{th} voltage acquisition chip acquires electric potential at the negative electrode of the (m−1)^{th} cell. The m^{th} voltage acquisition chip acquires electric potential at the positive electrode of the (m−1)^{th} cell.

In practice, the signal processing board receives the electric potential at the negative electrode of the (m−1)^{th} cell transmitted by the (m−1)^{th} voltage acquisition chip and the electric potential at the positive electrode of the (m−1)^{th} cell transmitted by the m^{th} voltage acquisition chip, and determines the voltage across the (m−1)^{th} cell based on the electric potential at the negative electrode of the (m−1)^{th} cell and the electric potential at the positive electrode of the (m−1)^{th} cell.

In S402, temperature sensors acquire temperature parameters of cells connected to the voltage acquisition chips where the temperature sensors are arranged and transmit the acquired temperature parameters to the signal processing board, respectively. The signal processing board analyzes the received voltage parameters and the received temperature parameters to determine whether the battery module is operating properly.

In some embodiments of the present application, the temperature sensor is placed on the voltage acquisition chip to conduct heat generated by the cell rapidly by fully exploiting thermal conductivity of the voltage acquisition chip. Therefore, the temperature of the cell can be measured timely and accurately. In addition, arranging the temperature sensor on the voltage acquisition chip can reduce the data acquisition circuit in size.

The data acquisition method according to the present application is appliable to the data acquisition circuit for the battery module. The data acquisition circuit according to the application includes a signal processing board and a signal acquisition board. The signal processing board includes an acquisition circuit module. The signal acquisition board is provided with n voltage acquisition chips and n−1 cells. The n voltage acquisition chips each are provided with a temperature sensor. The signal acquisition board is connected to the signal processing board through a connector. The first end of the (m−1)^{th} voltage acquisition chip is connected to the negative electrode of the (m−1)^{th} cell. The first end of the m^{th} voltage acquisition chip is connected to the positive electrode of the (m−1)^{th} cell. The second end of the voltage acquisition chip is connected to the signal processing board through the connector. The voltage acquisition chip acquires the voltage parameter of the cell connected to the voltage acquisition chip and transmit the acquired voltage parameter to the signal processing board. m is greater than or equal to 2 and less than or equal to n. The first end of the temperature sensor is connected to the acquisition circuit module in the signal processing board. The temperature sensor acquires the temperature parameter of the cell connected to the corresponding voltage acquisition chip, and transmits the acquired temperature parameter to the signal processing board. The signal processing board analyzes the received voltage parameters and temperature parameters to determine whether the battery module is operating properly. In this way, all cells in the battery module can be taken into account in the determination of whether the battery module is functioning properly or not, and the safety of the battery module cannot be guaranteed.

The same and similar parts of the various embodiments in this specification can be referred to each other, and each embodiment focuses on the differences from other embodiments. In particular, for the system or the system embodiment, since it is basically similar to the method embodiment, the description is relatively simple, and for related parts, please refer to the part of the description of the method embodiment. The systems and system embodiments described above are only illustrative, and the units described as separate components may or may not be physically separated, and the components shown as units may or may not be physical units, that is, it can be located in one place, or it can be distributed to multiple network elements. Part or all of the modules can be selected according to actual needs to achieve the purpose of the solution of this embodiment. It can be understood and implemented by those skilled in the art without creative effort.

Professionals can further realize that the units and algorithm steps of the examples described in conjunction with the embodiments disclosed herein can be implemented by electronic hardware, computer software or a combination of the two. In order to clearly illustrate the interchangeability of hardware and software, the composition and steps of each example have been generally described in terms of functions in the above description. Whether these functions are executed by hardware or software depends on the specific application and design constraints of the technical solution. Skilled artisans may use different methods to implement the described functions for each specific application, but such implementation should not be regarded as exceeding the scope of the present invention.

For the above description of the disclosed embodiments, the features recorded in each embodiment in this specification can be replaced or combined with each other, so that those skilled in the art can realize or use the present disclosure. Various modifications to these embodiments will be readily apparent to those skilled in the art, and the general principles defined herein may be implemented in other embodiments without departing from the spirit or scope of the invention. Therefore, the present disclosure will not be limited to the embodiments shown herein, but is to be accorded the widest scope consistent with the principles and novel features disclosed herein.

1. A data acquisition circuit for a battery module, comprising:
a signal processing board, wherein the signal processing board comprises an acquisition circuit module; and
a signal acquisition board, wherein the signal acquisition board is provided with n voltage acquisition chips and n−1 cells of the of the battery module, and the n voltage acquisition chips each are provided with a temperature sensor, wherein
the signal acquisition board is connected to the signal processing board through a connector;
a first end of an (m−1)^{th} voltage acquisition chip among the n voltage acquisition chips is connected to a negative electrode of an (m−1)^{th} cell among the n−1 cells, and a first end of an m^{th} voltage acquisition chip among the n voltage acquisition chips is connected to a positive electrode of the (m−1)^{th} cell;
for each of the n voltage acquisition chips, a second end of the voltage acquisition chip is connected to the signal processing board through the connector, and the voltage acquisition chip is configured to acquire a voltage parameter of the cell connected to the voltage acquisition chip and transmit the acquired voltage parameter to the signal processing board, wherein m is greater than or equal to 2 and less than or equal to n; and
a first end of the temperature sensor is connected to the acquisition circuit module, and the temperature sensor is configured to acquire a temperature parameter of the cell connected to the voltage acquisition chip corresponding to the temperature sensor and transmit the acquired temperature parameter to the signal processing board.

2. The data acquisition circuit according to claim 1, wherein the signal acquisition board is n in number and the connector is n in number, and wherein
an m^{th} signal acquisition board among the n signal acquisition boards is connected to the signal processing board through an m^{th} connector among the n connectors;
an (m−1)^{th} connector among the n connectors is arranged under the m^{th} signal acquisition board; and
an (m−1)^{th} signal acquisition board among the n signal acquisition boards is connected to the signal processing board through the (m−1)^{th} connector.

3. The data acquisition circuit according to claim 2, wherein the acquisition circuit module is n in number, and wherein
first ends of temperature sensors on a first signal acquisition board among the n signal acquisition boards are connected to a first acquisition circuit module among the n acquisition circuit modules on the signal processing board; and
first ends of the temperature sensors on the m^{th} signal acquisition board are connected to an m^{th} acquisition circuit module among the n acquisition circuit modules on the signal processing board.

4. The data acquisition circuit according to claim 1, wherein the acquisition circuit module comprises n temperature signal processing circuits, and wherein
a first end of a first temperature sensor in the signal acquisition board is connected to a first temperature signal processing circuit among the n temperature signal processing circuits in the acquisition circuit module; and
a first end of an m^{th} temperature sensor in the signal acquisition board is connected to an m^{th} temperature signal processing circuit among the n temperature signal processing circuits in the acquisition circuit module.

5. The data acquisition circuit according to claim 4, wherein the acquisition circuit module further comprises n filtering protection circuits, and wherein
the first end of the first temperature sensor in the signal acquisition board is connected to a first end of a first filtering protection circuit among the n filtering protection circuits in the acquisition circuit module, a second end of the first filtering protection circuit is connected to the first temperature signal processing circuit, and a third end of the first filtering protection circuit is grounded; and
the first end of the m^{th} temperature sensor in the signal acquisition board is connected to a first end of an m^{th} filtering protection circuit among the n filtering protection circuits in the acquisition circuit module, a second end of the m^{th} filtering protection circuit is connected to the m^{th} temperature signal processing circuit, and a third end of the m^{th} filtering protection circuit is grounded.

6. The data acquisition circuit according to claim 1, wherein the signal acquisition board comprises n fuses, and wherein
second ends of the n voltage acquisition chips are connected to first ends of the n fuses, respectively; and
second ends of the n fuses are connected to the connector, wherein the n voltage acquisition chips are connected to the signal acquisition board through the respective fuses and the connector.

7. The data acquisition circuit according to claim 1, wherein the signal acquisition board further comprises a first target fuse, and wherein
a third end of a first voltage acquisition chip among the n first voltage acquisition chips is connected to a first end of the first target fuse, and a second end of the first target fuse is connected to a ground terminal of the signal acquisition module through the connector.

8. The data acquisition circuit according to claim 1, wherein the signal acquisition board further comprises a second target fuse, and wherein
a second end of the temperature sensor is connected to a first end of the second target fuse, and a second end of the second target fuse is connected to a ground terminal of the signal acquisition module through the connector.

9. The data acquisition circuit according to claim 8, wherein the signal acquisition board further comprises n current limiting resistors, and wherein
a third end of a first temperature sensor among the n temperature sensors is connected to a first end of a first current limiting resistor among the n current limiting resistors, and a second end of the first current limiting resistor is connected to the first end of the second target fuse;
a third end of an m^{th} temperature sensor among the n current limiting resistors is connected to a first end of an m^{th} current limiting resistor among the n current limiting resistors, and a second end of the m^{th} current limiting resistor is connected to the first end of the second target fuse.

10. The data acquisition circuit according to claim 7, wherein the signal acquisition board further comprises a third target fuse, and wherein
a third end of an nth voltage acquisition chip among the n voltage acquisition chips is connected to the first end of the first target fuse; and
the second end of the first target fuse is connected to the signal processing board through the connector.

11. A data acquisition method for a battery module, wherein the method is applicable to a data acquisition circuit, the data acquisition circuit comprises a signal processing board and a signal acquisition board, the signal processing board comprises an acquisition circuit module, the signal acquisition board is provided with n voltage acquisition chips and n−1 cells of the battery module, and the n voltage acquisition chips each are provided with a temperature sensor, and the method comprises:
acquiring voltage parameters of cells connected to voltage acquisition chips and transmitting the acquired voltage parameters to the signal processing board, by the voltage acquisition chips, respectively; and
acquiring temperature parameters of the cells connected to the voltage acquisition chips where temperature sensors are arranged and transmitting the acquired temperature parameters to the signal processing board by the temperature sensors, respectively, for the signal processing board to analyze the received voltage parameters and the received temperature parameters to determine whether the battery module is operating properly.
